(19) United States
(12) Patent Application Publication
(10) Pub. No.: US 2026/0173303 A1
(43) Pub. Date: Jun. 18, 2026

(54) BATTERY CHARGER

(71) Applicant: MILWAUKEE ELECTRIC TOOL CORPORATION, Brookfield, WI (US)

(72) Inventors: Matthew J. Herro, Pewaukee, WI (US); Anderson J. Ernst, Seal Beach, CA (US); Joel D. Snyder, Menomonee Falls, WI (US); Carson G. Taylor, Madison, WI (US); Keith G. Koch, Kenosha, WI (US); Jacob D. Rosenthal, Brookfield, WI (US)

(21) Appl. No.: 19/413,407

(22) Filed: Dec. 9, 2025

Related U.S. Application Data
(60) Provisional application No. 63/734,378, filed on Dec. 16, 2024.

(51) Int. Cl. H05K 7/20; H01M 10/613; H01M 10/667; H05K 7/02

(52) U.S. Cl. CPC H05K 7/20145; H01M 10/613; H01M 10/667; H05K 7/026; H05K 7/20172

(57) ABSTRACT

A battery charger may include a housing including a plurality of battery interfaces. The battery charger may include a printed circuit board (PCB) disposed in the housing. The battery charger may include a fan disposed in the housing, the fan configured to rotate about a rotational axis to generate an airflow, the rotational axis extending through the PCB, wherein the airflow passes through at least two battery interfaces of the plurality of battery interfaces.

### CROSS-REFERENCE TO RELATED APPLICATIONS

This application claims priority to U.S. Provisional Application No. 63/734,378 filed Dec. 16, 2024, the entire contents of which are incorporated herein.

### FIELD

The present disclosure relates to a battery charger. In particular, a battery charger that is configured to receive a removable battery pack from a power tool.

### BACKGROUND

Power tools are increasingly dependent on rechargeable batteries. Therefore, efficient recharging of batteries is a goal of the industry.

### SUMMARY

The present disclosure provides, in one aspect, a battery charger including a housing including a plurality of battery interfaces, a printed circuit board (PCB) disposed in the housing, and a fan disposed in the housing, the fan configured to rotate about a rotational axis to generate an airflow, the rotational axis extending through the PCB. The airflow passes through at least two battery interfaces of the plurality of battery interfaces.

The present disclosure provides, in another aspect, a battery charger including a printed circuit board (PCB) and a housing. The housing includes a base, a column including a first end coupled to the base and a second end opposite the first end, the column extending from the base in a height direction, a baffle disposed in the column nearer to the second end than to the first end, and a PCB enclosure at least partially surrounding the PCB. The PCB enclosure is disposed in the base. The battery charger includes a fan disposed in the housing, the fan configured to rotate about a rotational axis to generate an airflow, the rotational axis extending through the PCB and through the column in the height direction. The baffle is configured to direct at least a portion of the airflow.

The present disclosure provides, in another aspect, a battery charger including a housing having a base. The base includes a plurality of air inlets defined therein and a column extending from the base. The column includes a plurality of battery interfaces disposed thereon and a plurality of air outlets defined therein. The battery charger includes a printed circuit board (PCB) disposed in the base and a fan disposed in the housing that is configured to induce an airflow. The airflow travels into the base through the air inlets, across the PCB, away from the PCB toward the fan, away from the fan, through the column, and out of the column through the plurality of outlets to thereby cool battery packs coupled to the plurality of battery interfaces.

### BRIEF DESCRIPTION OF THE DRAWINGS

FIG. 1 is a perspective view of a battery charger.

FIG. 2 is side view of the battery charger of FIG. 1.

FIG. 3 a rear perspective view of the battery charger of FIG. 1.

FIG. 4 is a top view of the battery charger of FIG. 1.

FIG. 5 is a rear view of the battery charger of FIG. 1.

FIG. 6 is a cross section view of the battery charger of FIG. 1, taken along section 6-6 in FIG. 4.

FIG. 7 is a cross section view of the battery charger of FIG. 1, taken along section 7-7 in FIG. 5.

Before any constructions of the disclosure are explained in detail, it is to be understood that the disclosure is not limited in its application to the details of construction and the arrangement of components set forth in the following description or illustrated in the following drawings. The disclosure is capable of other constructions and of being practiced or of being carried out in various ways.

### DETAILED DESCRIPTION

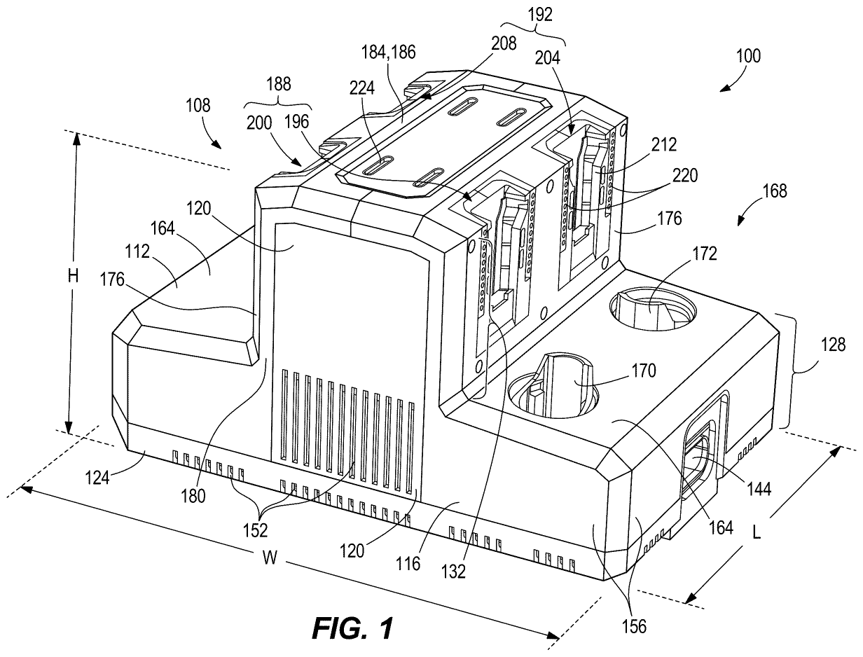

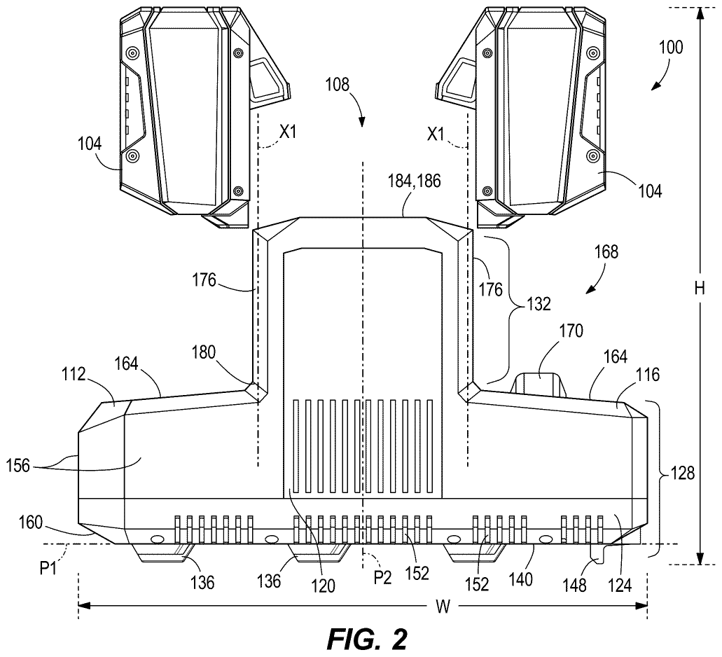

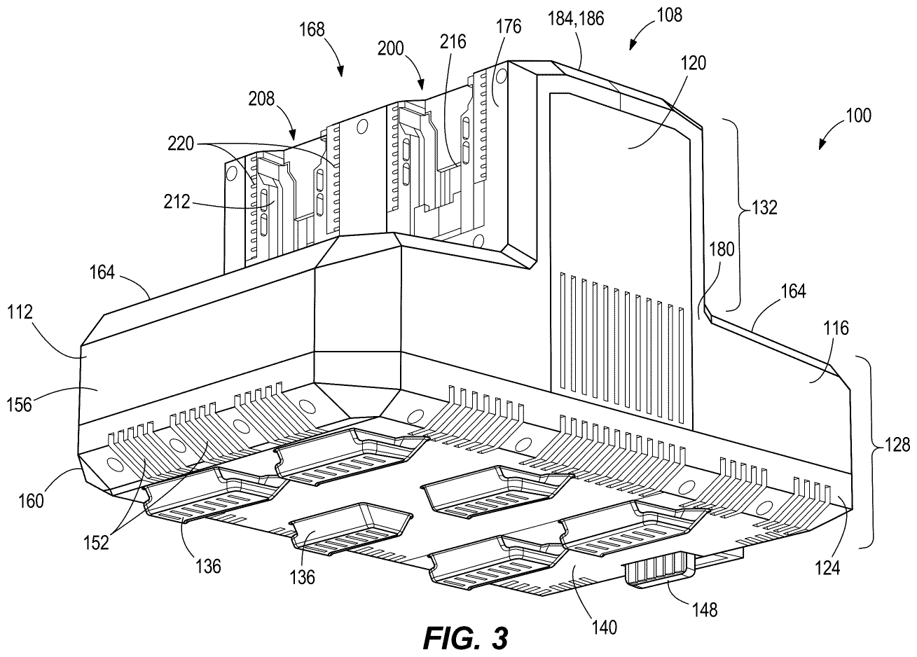

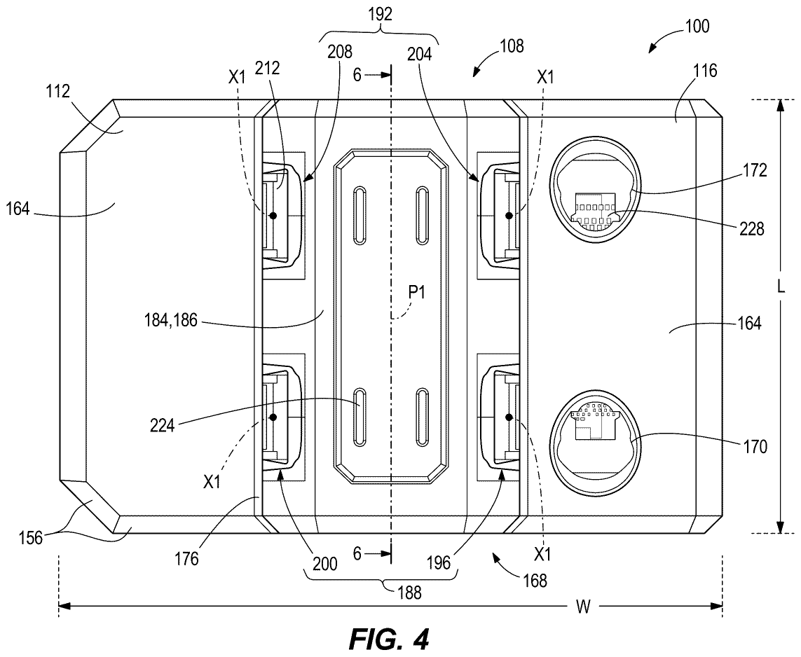

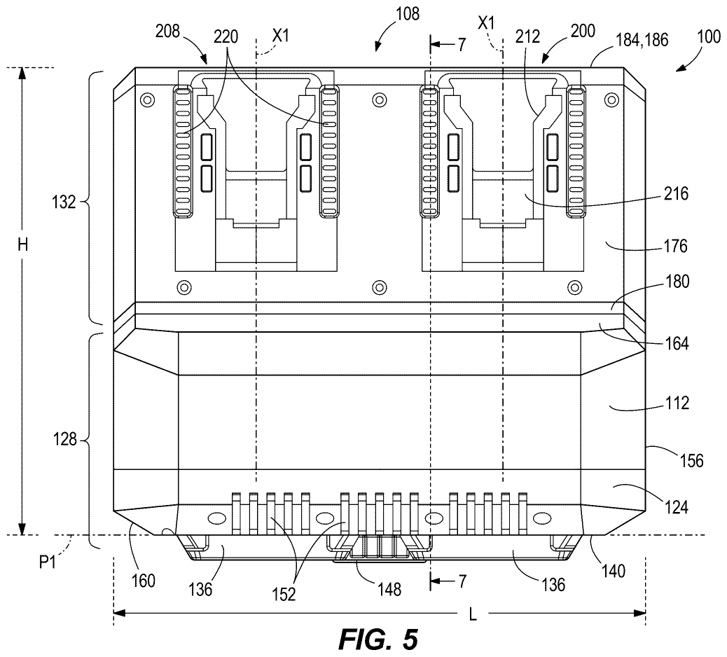

FIGS. 1-5 illustrates a battery charger 100 operable to charge one or more a battery packs 104 (FIG. 2) coupled to the battery charger 100. The battery charger 100 includes a housing 108. In the illustrated construction, the housing 108 includes a first clamshell 112, a second clamshell 116, intermediate plates 120, and a bottom plate 124. The first and second clamshells 112, 116, the intermediate plates 120, and the bottom plate 124 are coupled together to form a base 128 and a column 132 of the housing 108. It is worth noting that in other constructions, the housing 108 is not limited to the components (e.g., the first and second clamshells 112, 116, the intermediate plates 120, the bottom plate 124) illustrated in FIG. 1. For instance, the base 128 may be constructed of a single piece and the column 132 may be constructed of a single piece coupled to the base 128.

The base 128 includes a plurality of cleats 136 extending therefrom (FIGS. 2-3 and 5). In the illustrated construction, the base 128 includes six cleats 136. In other constructions, the base 128 may include fewer or more cleats 136 (e.g., a single cleat 136 or more than six cleats 136). The illustrated cleats 136 extend from a bottom wall 140 of the base 128. The bottom wall 140 partially defines a plane P1. The bottom wall 140 extends in a width direction W and a length direction L that is transverse (e.g., perpendicular) to the width direction W. The cleats 136 are configured to cooperate with recesses on a support structure. For example, the cleats 136 may be configured to cooperate or interface with a toolbox, a wall plate, or the like of the PACKOUT modular storage system sold by Milwaukee Tool. The base 128 includes an actuator 144 having a projection 148 extending downwardly from the bottom wall 140. The actuator 144 and the projection 148 are biased by a spring. In the resting position, the actuator 144 and projection 148 are biased by the spring such that the projection 148 projects from the base 128. A user may retract the projection 148 into the housing by manipulating the actuator 144. The projection 148 is configured to engage and disengage a corresponding recess on the support structure to releasably secure the battery charger 100 to the support structure.

The base 128 includes a plurality of vents 152. In the illustrated construction, vents of the plurality of vents 152 are at least partially disposed on the bottom wall 140. The base 128 includes walls 156 that extend from the bottom wall 140 in a height direction H. In the illustrated construction, the height direction H is transverse (e.g., perpendicular) to the width and length directions W, L. In the illustrated construction, vents of the plurality of vents 152 are at least partially disposed on the walls 156. In the illustrated construction, the base 128 includes a chamfer 160 between the bottom wall 140 and the walls 156. The chamfer 160 includes vents of the plurality of vents 152 that couple vents of the bottom wall 140 to the vents of the walls 156. In other constructions, the vents of the chamfer 160 do not couple the vents of the bottom wall 140 and the vents of the walls 156 together (e.g., the vents are separate from one another). The base 128 includes a pair of walls 164 that extend between the walls 156 and the column 132. The housing 108 includes a plurality of battery interfaces 168 disposed on the base 128 and the column 132. In the illustrated construction, a wall of the pair of walls 164 nearer to the actuator 144 includes a first battery interface 170 and a second battery interface 172 of the plurality of battery interfaces 168.

The column 132 extends from the base 128 in the height direction H. Specifically, the column 132 includes walls 176 extending from the walls 164 in the height direction H. In the illustrated construction, portions of the walls 156 of the base 128 extend past the walls 164 in the height direction H to form part of the column 132 (e.g., extending between the walls 176 in the width direction W). The intersection between the walls 164 and the walls 176 is considered to be a first end 180 of the column 132. The column 132 includes a wall 184 extending between the walls 176 and the walls 156. The wall 184 is generally parallel to the plane P1 and is disposed at a second end 186 that is opposite the first end 180.

The column 132 includes a first pair of battery interfaces 188 and a second pair of battery interfaces 192 of the plurality of battery interfaces 168. In the illustrated construction, the first and second pair of battery interfaces 188, 192 are disposed on the walls 176.

In the illustrated construction, battery interfaces of the first pair of battery interfaces 188 are disposed on opposing sides of the column 132. Specifically, a battery interface 196 of the first pair of battery interfaces 188 is disposed on a wall of the walls 176 nearer to the first and

second battery interfaces 170, 172. Another battery interface 200 of the first pair of battery interfaces 188 is disposed on the other wall of the walls 176. In other words, a plane P2 bisects the column in a direction parallel to the length direction L. The battery interfaces 196, 200 of the first pair of battery interfaces 188 are disposed on opposite sides of the plane P2.

In the illustrated construction, battery interfaces of the second pair of battery interfaces 192 are disposed on opposing sides of the column 132. Specifically, a battery interface 204 of the second pair of battery interfaces 192 is disposed on the wall of the walls 176 nearer to the first and second battery interfaces 170, 172. Another battery interface 208 of the second pair of battery interfaces 192 is disposed on the other wall of the walls 176. In other words, the battery interfaces 204, 208 of the second pair of battery interfaces 208 are disposed on a opposite sides of the plane P2.

Each battery interface of the first and second pair of the battery interfaces 188, 192 include a slot 212 configured to receive the battery pack 104, an aperture 216, and vents 220. In the illustrated construction, the slot 212, the aperture 216, and the vents 220 are defined by the walls 176. The slot 212 is configured to receive the battery pack 104 along an insertion axis X1 such that the battery pack 104 is charged at the respective interface. The wall 184 includes indicators 224 corresponding to the plurality of battery interfaces 168. The indicators 224 indicate the status of the battery back 104 (e.g., whether the battery pack 104 is fully charged).

The battery pack 104 may include multiple battery cells having, for example, a lithium (Li), lithium-ion (Li-ion), or other lithium-based chemistry. For example, the battery cells may have a chemistry of lithium-cobalt (Li—Co), lithium-manganese (Li—Mn) spinel, or Li—Mn nickel. In such constructions, each battery cell may have a nominal voltage of about, for example, 3.6V, 4.0V, or 4.2V. In other constructions, the battery cells may have a nickel-cadmium, nickel-metal hydride, or lead acid battery chemistry. In further constructions, the battery pack 104 may include fewer or more battery cells, and/or the battery cells may have a different nominal voltage. The battery pack 104 is connectable to and operable to power various motorized power tools (e.g., a cut-off saw, a miter saw, a table saw, a core drill, an auger, a breaker, a demolition hammer, a compactor, a vibrator, a compressor, a drain cleaner, a welder, a cable tugger, a pump, etc.), outdoor tools (e.g., a chain saw, a string trimmer, a hedge trimmer, a blower, a lawn mower, etc.), other motorized devices (e.g., vehicles, utility carts, a material handling cart, etc.), and non-motorized electrical devices (e.g., a power supply, a light, an AC/DC adapter, a generator, etc.).

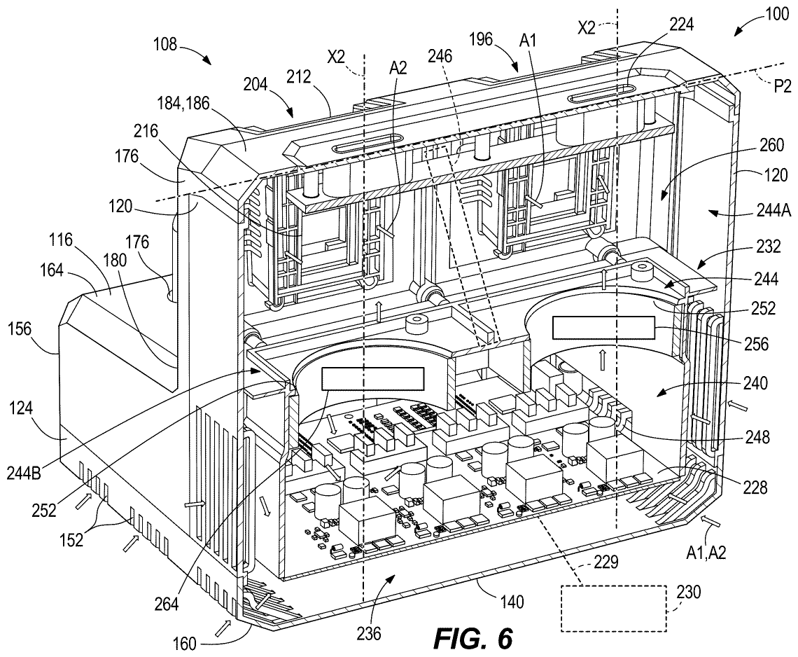

FIG. 6 illustrates a battery charger 100 including a printed circuit board (PCB) 228. The PCB 228 includes electrical connection interfaces, such as a cable or power cord 229, configured to receive power from an external power source, such as electricity from a wall outlet 230. In some constructions, the external power source is a DC power source. In some constructions, the external power source is an AC power source. For example, the AC power source may be a conventional wall outlet, such as a 120 V outlet or a 240 V outlet, found in North America.

The PCB 228 is electronically coupled to each battery interface of the plurality of battery interfaces 168 such that power is provide to each of the battery interfaces. The PCB 228 is disposed in the housing 108 and is generally parallel to the plane P1. Specially, the housing 108 includes a PCB enclosure 232 that at least partially surrounds the PCB 228. In the illustrated construction, the PCB enclosure 232 is disposed in the base 128 with at least a portion disposed in the column 132. In the illustrated construction, a top the PCB enclosure 232 is coupled to the column 132 and a bottom of the PCB enclosure 232 is coupled to the base 128. In other constructions, the PCB enclosure 232 only coupled to the base 128 or to the column 132.

A base chamber 236 is defined between the base 128 and the PCB enclosure 232. A PCB chamber 240 is defined within the PCB enclosure 232. A column chamber 244 is defined between the PCB enclosure 232 and the column 132. In some constructions, the column 132 optionally includes a divider 246. In the illustrated construction, the divider 246 splits the column chamber 244 in half. In other words, the first pair of battery interfaces 188 are not fluidly connected to the second pair of battery interfaces 192 via the column chamber 244. More particularly, the divider 246 separates the column chamber 244 into a first column chamber 244A and a second column chamber 244B. The first column chamber 244A is exclusively in fluid communication with the first pair of battery interfaces 188 (e.g., the battery interfaces 196, 200). The second column chamber 244B is exclusively in fluid communication with the second pair of battery interfaces 192 (e.g., the battery interfaces 204, 208). In a construction without the divider 246, the first and second pair of battery interfaces 188, 192 are fluidly connected via the column chamber 244 (e.g., the battery interfaces 196-208).

The PCB enclosure 232 includes a one or more base apertures 248 that fluidly connect the base chamber 236 to the PCB chamber 240. The PCB enclosure 232 includes one or more column apertures 252 that fluidly connect the PCB chamber 240 to the column chamber 244. In the illustrated construction, the chambers 236, 240, and 244 are fluidly connected via the apertures 248, 252. In other words, aside from the apertures 248, 252, the chambers 236, 240, and 244 are sealed from one another.

The battery charger 100 includes a first fan 256 disposed in the housing 108 and is configured to rotate about a rotational axis X2. In the illustrated construction, the rotational axis X2 extends through the PCB 228 and through the column 132 in the height direction H. Specifically, the rotational axis X2 is perpendicular to the PCB 228. The rotational axis X2 is parallel to the insertion axis X1. The first fan 256 is disposed in an aperture of the column apertures 252.

In some constructions, the battery charger 100 includes a single fan (e.g., the first fan 256). In some constructions, the charger includes a plurality of fans 260. For instance, the first fan 256 is a fan of a plurality of fans 260. In the illustrated construction, the charger includes a second fan 264 of the plurality of fans 260. The second fan 264 is received in the housing 108 and more specifically, in an aperture of the column apertures 252. The plurality of fans 260 (e.g., the first and second fan 256, 264) are aligned in a direction transverse to the rotational axis X2 of the first fan 256. In the illustrated construction, the plurality of fans 260 are aligned along the plane P2.

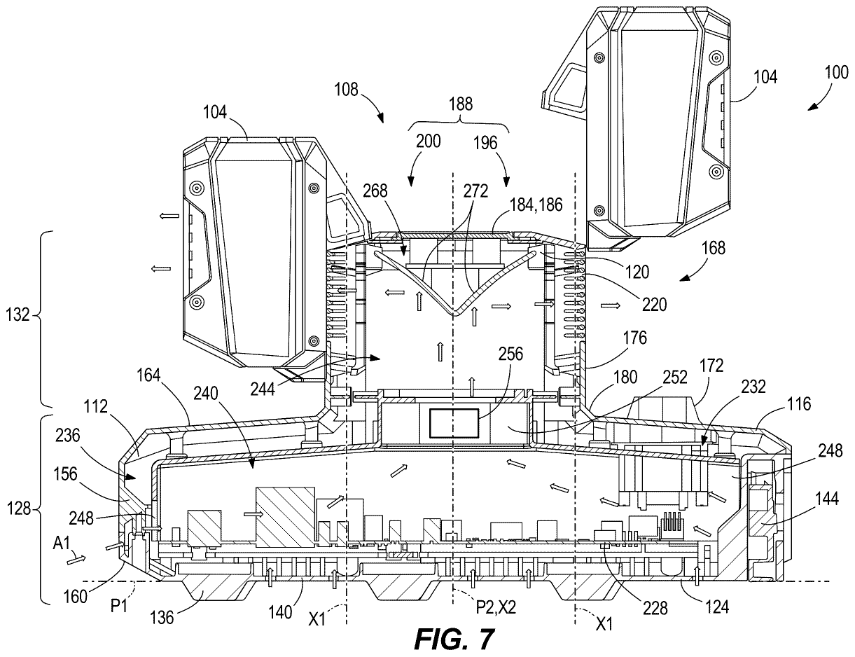

FIG. 7 illustrates the housing 108 including a baffle 268 (hidden in FIG. 6). In the illustrated construction, the baffle 268 is disposed in the column 132 near to the second end 186. Although not illustrated in FIG. 7, the baffle 268 extends along an entire length of the column 132 in the length direction L. The baffle 268 includes a pair of concave walls 272. In the illustrated construction, a portion of the baffle 268 intersects the rotational axis X2.

The charging of battery packs 104 may increase heat experienced by the battery charger 100. For instance, the PCB 228 and the plurality of battery interfaces 168 may increase in temperature when the battery packs 104 are charged. Additionally, the battery packs 104 may increase in temperature. As such, thermal management of the battery charger 100 decreases the temperature of the battery charger 100. In the illustrated construction, the first fan 256 contributes to the thermal management of the battery charger 100. In other constructions, the second fan 264 contributes to the thermal management of the battery charger 100 in addition to the first fan 256. That is, the thermal management of the battery charger 100 may be accomplished with a single fan or multiple fans.

As schematically illustrated in FIGS. 6-7, the first fan 256 is configured to generate an airflow A1. In the illustrated construction, the first airflow A1 enters the housing 108 via the plurality of vents 152 (e.g., inlet vents). Specifically, the airflow A1 enters the base 128 through the plurality of vents 152 and into the base chamber 236. Then the airflow A1 passes from the base chamber 236, through the base apertures 248, and into the PCB chamber 240. The airflow A1 cools the PCB 228 as it enters the PCB chamber 240 and flows across the PCB 228. Then the airflow A1 travels from the PCB chamber 240 to the column apertures 252. Specifically, the airflow A1 enters the first fan 256 that is disposed in the aperture of the column apertures 252 and is directed along the rotational axis A2 and toward the second end 186 of the column 132 (e.g., away from the fan 256). The PCB 228 is “upstream” relative to the first fan 256 since the airflow A1 passes over the PCB 228 prior to reaching the first fan 256. The airflow A1 is directed from the first fan 256, along the rotation axis X2, and into the column chamber 244. The exit path of the airflow A1 is dependent upon whether the housing 108 includes the divider 246.

In a construction having the housing 108 with the divider 246, at least a portion of the first airflow A1 is redirected by the baffle 268 and toward the first pair of battery interfaces 188. The divider 246 prevents the airflow A1 from reaching the second pair of battery interfaces 192 because the airflow A1 is contained in the first column chamber 244A. The baffle 268 redirects the airflow A1 in a direction transverse (e.g., perpendicular) to the rotational axis X2. The airflow A1 exits the column 132 through the aperture 216 and vents 220 (e.g., outlet vents) of the first pair of battery interfaces 188. The airflow A1 is directed through the battery pack 104 to cool the battery pack 104 during charging.

In a construction having the housing 108 without the divider 246, at least a portion the first airflow A1 is redirected by the baffle 268 and toward the first and/or second pair of battery interfaces 188, 192. In other words, the airflow A1 may flow to either of the pair of the battery interfaces 188, 192. The baffle 268 redirects the airflow A1 in a direction transverse (e.g., perpendicular) to the rotational axis X2. The airflow A1 exits the column 132 through the aperture 216 and vents 220 (e.g., outlet vents) of the first and second pair of battery interfaces 188, 192. The airflow A1 is directed through the battery pack 104 to cool the battery pack 104 during charging.

The influence of the second fan 264 on airflow is dependent on whether the housing 108 includes the divider 246. In a construction having the housing 108 without the divider 246, the second fan 264 contributes to the airflow A1. The column chamber 244 is a single chamber that receives the airflow A1 from the fans 256, 264. As such, the airflow is distributed to the first and/or second pair of battery interfaces 188, 192.

In a construction having the housing 108 with the divider 246, the second fan 264 generates another airflow A2 with a path that is distinct from the airflow A1. That is, the airflow A1 is a first airflow of a plurality of airflows and another airflow A2 is a second airflow of the plaurlity of airflows. The path of the airflows A1, A2 from the plurality of vents 152 to the PCB chamber 240 is the same. However, the paths of the airflows A1, A2 starting the fans 256, 264, respectively, is distinct. As discussed above, the airflow A1 is travels through the first column chamber 244A and is redirected by the baffle 268 to the first pair of battery interfaces 188. At least a portion of the airflow A2 is redirected by the baffle 268 and toward the second pair of battery interfaces 192. The divider 246 prevents the airflow A2 from reaching the first pair of battery interfaces 188 because the airflow A2 is contained in the second column chamber 244B. The baffle 268 redirects the airflow A2 in a direction transverse (e.g., perpendicular) to the rotational axis X2. The airflow A1 exits the column 132 through the aperture 216 and vents 220 (e.g., outlet vents) of the second pair of battery interfaces 192. The airflow A2 is directed through the battery pack 104 to cool the battery pack 104 during charging.

Although the disclosure has been described in detail with reference to certain preferred constructions, variations and modifications exist within the scope and spirit of one or more independent aspects of the disclosure as described.

What is claimed is:

1. A battery charger comprising:
a housing including a plurality of battery interfaces;
a printed circuit board (PCB) disposed in the housing; and
a fan disposed in the housing, the fan configured to rotate about a rotational axis to generate an airflow, the rotational axis extending through the PCB,
wherein the airflow passes through at least two battery interfaces of the plurality of battery interfaces.

2. The battery charger of claim 1, wherein the rotational axis is perpendicular to the PCB.

3. The battery charger of claim 1, wherein the fan is a first fan of a plurality of fans and wherein the plurality of fans are aligned in a direction transverse to the rotational axis.

4. The battery charger of claim 3, wherein the plurality of fans include a second fan configured to contribute to the airflow.

5. The battery charger of claim 3, wherein the airflow is a first airflow of a plurality of airflows, wherein the plurality of fans include a second fan configured to generate a second airflow of the plurality of airflows, wherein the housing includes a wall separating the first airflow from the second airflow.

6. The battery charger of claim 5, wherein the first airflow is configured to pass through the at least two battery interfaces of the plurality of battery interfaces, wherein the plurality of battery interfaces includes another battery interface, and wherein the second airflow is configured to pass through the another battery interface.

7. The battery charger of claim 1, wherein the airflow is configured to pass over the PCB prior to the fan.

8. The battery charger of claim 1, wherein each of the plurality of battery interfaces include a vent and slot configured to receive a battery along an insertion axis.

9. The battery charger of claim 8, wherein the housing includes a baffle configured to redirect at least a portion of the airflow toward the vent and wherein the insertion axis is parallel to the rotational axis.

10. A battery charger comprising:
a printed circuit board (PCB);
a housing including
a base,
a column including a first end coupled to the base and a second end opposite the first end, the column extending from the base in a height direction,
a baffle disposed in the column nearer to the second end than to the first end, and
a PCB enclosure at least partially surrounding the PCB, the PCB enclosure disposed in the base; and
a fan disposed in the housing, the fan configured to rotate about a rotational axis to generate an airflow, the rotational axis extending through the PCB and through the column in the height direction,
wherein the baffle is configured to direct at least a portion of the airflow.

11. The battery charger of claim 10, wherein the baffle includes a pair of concave walls.

12. The battery charger of claim 10, wherein the rotational axis is perpendicular to the PCB and wherein a portion of the baffle intersects the rotational axis.

13. The battery charger of claim 10, wherein the column includes a plurality of battery interfaces each including a vent and a slot configured to receive a battery along an insertion axis that is parallel to the rotational axis.

14. The battery charger of claim 13, wherein the base includes inlet vents and wherein the airflow enters the housing through the inlet vents and exits the housing through the vents of the plurality of battery interfaces.

15. The battery charger of claim 10, wherein a base chamber is defined between the base and the PCB enclosure, wherein a PCB chamber is defined within the PCB enclosure, and wherein a column chamber is defined between the PCB enclosure and the column.

16. The battery charger of claim 15, wherein the PCB enclosure includes a base aperture that fluidly connects the base chamber to the PCB chamber.

17. The battery charger of claim 15, wherein the PCB enclosure includes a column aperture that fluidly connects the PCB chamber to the column chamber, wherein the fan is received in the column aperture.

18. The battery charger of claim 17, wherein the airflow is configured to cool the PCB.

19. A battery charger comprising:
a housing including
a base including a plurality of air inlets defined therein, and
a column extending from the base, the column including
a plurality of battery interfaces disposed thereon, and
a plurality of air outlets defined therein;
a printed circuit board (PCB) disposed in the base; and
a fan disposed in the housing, the fan configured to induce an airflow that travels
into the base through the air inlets,
across the PCB,
away from the PCB toward the fan,
away from the fan,
through the column, and
out of the column through the plurality of outlets to thereby cool battery packs coupled to the plurality of battery interfaces.

20. The battery charger of claim 19, wherein the airflow travels away from the fan along a rotational axis of the fan and travels perpendicularly to the rotational axis out of the column through the plurality of outlets.
